(19) United States
(12) Patent Application Publication
(10) Pub. No.: US 2006/0081337 A1
(43) Pub. Date: Apr. 20, 2006

(54) Capacitive coupling plasma processing apparatus

(76) Inventors: Shinji Himori, Nirasaki-shi (JP); Kimihiro Higuchi, Nirasaki-shi (JP); Tatsuo Matsudo, Nirasaki-shi (JP); Etsuo Iijima, Amagasaki-shi (JP); Hiroharu Ito, Nirasaki-shi (JP); Shoichiro Matsuyama, Nirasaki-shi (JP); Noriaki Imai, Nirasaki-shi (JP); Kazuya Nagaseki, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/292,368

(22) Filed: Dec. 2, 2005

Related U.S. Application Data
(60) Provisional application No. 60/658,157, filed on Mar. 4, 2005.

(30) Foreign Application Priority Data
Mar. 12, 2004 (JP) 2004-350995

(51) Int. Cl. C23F 1/00; C23C 14/00

(52) U.S. Cl. 156/345.47; 204/298.01

(57) ABSTRACT

A capacitive coupling plasma processing apparatus includes a process chamber configured to have a vacuum atmosphere, and a process gas supply section configured to supply a process gas into the chamber. In the chamber, a first electrode serving as a cathode electrode, and a second electrode grounded to serve as an anode electrode are disposed opposite each other. An RF power supply is disposed to supply an RF power to the first electrode to form an RF electric field within a plasma generation region between the first and second electrodes, so as to turn the process gas into plasma. The target substrate is supported by a support member between the first and second electrodes such that a process target surface thereof faces the second electrode. The second electrode includes a conductive counter surface facing the first electrode and exposed to the plasma generation region.

### CROSS-REFERENCE TO RELATED APPLICATIONS

This application claims the benefit of U.S. Provisional Application No. 60/658,157, filed Mar. 4, 2005.

This application is based upon and claims the benefit of priority from prior Japanese Patent Application No. 2004-350995, filed Dec. 3, 2004, the entire contents of which are incorporated herein by reference.

### BACKGROUND OF THE INVENTION

1. Field of the Invention

The present invention relates to a plasma processing apparatus of the capacitive coupling type, used for performing a plasma process on a target substrate in, e.g. a semiconductor processing system. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or a glass substrate used for an LCD (Liquid Crystal Display) or FPD (Flat Panel Display), by forming semiconductor layers, insulating layers, and conductive layers in predetermined patterns on the target substrate.

2. Description of the Related Art

For example, in manufacturing semiconductor devices, plasma processes, such as etching, sputtering, and CVD (Chemical Vapor Deposition), are often used for processing a target substrate or semiconductor wafer. There are various plasma processing apparatuses for performing such plasma processes, but parallel-plate plasma processing apparatuses of the capacitive coupling type are the ones in mainstream use.

In general, a parallel-plate plasma etching apparatus of the capacitive coupling type includes a process chamber with a pair of parallel-plate electrodes (upper and lower electrodes) disposed therein. When a process performed, while a process gas is supplied into the chamber, an RF (radio frequency) power is applied to one of the electrodes to form an RF electric field between the electrodes, thereby causing RF electric discharge. The process gas is turned into plasma by the RF electric field, thereby performing, e.g. plasma etching on a predetermined layer disposed on a semiconductor wafer.

For example, there is an apparatus of this kind in which an RF power is applied to the lower electrode on which the semiconductor wafer is placed. In this case, the lower electrode serves as a cathode electrode, and the upper electrode serves as an anode electrode. The RF power applied to the lower electrode is used for plasma generation and also for an RF bias applied to the target substrate.

In the parallel-plate plasma processing apparatus of the capacitive coupling type, the upper electrode serving as an anode electrode needs to be protected from metal contamination and wear-out. For this reason, the upper electrode is formed of a metal base body having a surface covered with a coating made of an oxide film or insulative ceramic with high resistance to plasma, such as Y₂O₃.

Plasma is generated by RF electric discharge caused between the electrodes, and electron and ion currents generated thereby are neutralized at the ground potential. Accordingly, relative to the ground potential, the insulating film covering the upper electrode comes to have a potential by which the plasma potential is determined.

In recent years, design rules in manufacturing semiconductor devices have been increasingly miniaturized. Particularly, in plasma etching, it is required to improve the dimensional accuracy, selectivity relative to the mask and under-layer, and planar uniformity of the etching. For this reason, the recent trend is to use a lower pressure and lower ion energy in the process field within a chamber. This trend has brought about a use of an RF power with a frequency of 40 MHz or more, which is far higher than the frequency conventionally used.

However, where a lower pressure and lower ion energy are used, as described above, it becomes necessary to address a decrease in the planar uniformity of plasma potential, which previously had been negligible. Specifically, in conventional apparatuses using high ion energy, poor planar uniformity of plasma potential does not cause a serious problem. However, as the pressure and ion energy are set to be lower, poor planar uniformity of plasma potential can easily make the process less uniform and easily cause charge-up damage.

In this respect, Patent Document 1 (U.S. Pat. No. 6,624,084) discloses a technique concerning a plasma processing apparatus. Specifically, this document discloses a technique of improving the planar uniformity of self-bias on a wafer generated by RF bias application, to reduce micro defects, such as charge-up damage. In order to achieve this, current path reform means is disposed for that portion of the RF current path of the RF bias applied to the wafer that is close to the periphery of the wafer, to cause an RF current to flow toward the surface of the counter electrode facing the wafer. Alternatively, impedance adjusting means is used to cause the impedance from the RF bias to ground to be almost uniform planarly on the wafer.

However, the technique of Patent Document 1 requires the current path reform means or impedance adjusting means and thus makes the apparatus structure complicated. Further, this technique is not necessary sufficient in the planar uniformity of plasma processing.

### BRIEF SUMMARY OF THE INVENTION

An object of the present invention to provide a plasma processing apparatus of the capacitive coupling type, which brings about a high planar uniformity of plasma processing, and prevents charge-up damage.

According to a first aspect of the present invention, there is provided a capacitive coupling plasma processing apparatus comprising:

a process chamber configured to have a vacuum atmosphere;

a process gas supply section configured to supply a process gas into the chamber;

a first electrode disposed in the chamber and configured to serve as a cathode electrode;

a second electrode disposed opposite the first electrode in the chamber and grounded to serve as an anode electrode;

an RF power supply configured to supply an RF power to the first electrode to form an RF electric field within a plasma generation region between the first and second electrodes, so as to turn the process gas into plasma by the RF electric field; and

a support member configured to support the target substrate between the first and second electrodes such that a process target surface of the target substrate faces the second electrode,

wherein the second electrode comprises a conductive counter surface facing the first electrode and exposed to the plasma generation region.

In the apparatus according to the first aspect, an electric current easily flows on the counter surface of the second electrode in the radial direction (planar direction). Accordingly, the potential on the counter surface of the second electrode is made even in the radial direction, so the potential gradient thereon becomes very small in the radial direction. In this case, the floating potential in plasma comes to have essentially no gradient near the second electrode serving as an anode electrode. Consequently, the first electrode serving as a cathode electrode receives ion energy incident thereon with a uniform distribution. Further, the uniform ion energy brings about a uniform electron energy in plasma generation, thereby resulting in a uniform electron density distribution. Consequently, it is possible to improve the uniformity of the plasma process, and reduce the charge-up damage. Since the floating potential in plasma and the plasma potential exhibit the same behavior in change, the plasma potential will be used in place of the floating potential in plasma for explanation hereinafter.

In the apparatus according to the first aspect, the second electrode may comprise a conductive main body, and a conductive layer disposed on a surface of the main body facing the first electrode, such that the conductive counter surface is defined by a surface of the conductive layer. In this case, without reference to the material of the main body, the counter surface of the second electrode can have a desired conductivity.

Further, the second electrode may further comprise an insulating layer interposed between the main body and the conductive layer. In this case, the advantages of the conductive layer described can be obtained in addition to the protection function of the insulating film conventionally used. Further, since the conductive layer can be formed on a conventional upper electrode, the apparatus structure does not require a large change.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing a plasma etching apparatus as a plasma processing apparatus according to an embodiment of the present invention;

FIG. 2 is a sectional view schematically showing a structure where an RF power supply for plasma generation and an RF power supply for ion attraction are connected to a lower electrode used as a support table;

FIG. 3 is a view schematically showing the structure of an electrode plate used as an upper electrode in a conventional plasma etching apparatus;

FIG. 4 is a view showing electron density distribution and plasma potential distribution in plasma where the conventional plasma etching apparatus is used;

FIG. 5 is a view schematically showing the structure of an electrode plate usable as an upper electrode in the plasma etching apparatus shown in FIG. 1;

FIG. 6 is a view showing electron density distribution and plasma potential distribution in plasma where the plasma etching apparatus shown in FIG. 1 is used;

FIG. 7 is a sectional view schematically showing a structure where a conductive surface layer is formed on the inner surface of a chamber to be continuous from a conductive layer on the electrode plate;

FIG. 8 is a sectional view schematically showing a structure where a conductive layer on an electrode plate is grounded through a variable DC (direct current) power supply connected thereto;

FIG. 9 is a view schematically showing the structure of another electrode plate usable as an upper electrode in the plasma etching apparatus shown in FIG. 1;

FIG. 10 is a graph showing plasma potential planar distribution obtained by a present example 1 (an electrode plate with a Cu tape attached thereon as a conductive layer) and a comparative example 1 (a conventional electrode plate), where each of them was used for performing a plasma process on a wafer at an RF power of 500 W;

FIGS. 11A and 11B are graphs showing plasma potential planar distribution obtained by a present example 2 (an electrode plate with a Si tape attached thereon as a conductive layer) and the comparative example 1 (the conventional electrode plate), where each of them was used for performing a plasma process z at RF powers of 500 W and 2400 W, respectively;

FIG. 12 is a view schematically showing a device structure used for testing charge-up damage resistance; and

FIGS. 13A and 13B are views showing and comparing generation rates of charge-up damage rendered by the comparative example 1 and present example 1, respectively.

### DETAILED DESCRIPTION OF THE INVENTION

Embodiments of the present invention will now be described with reference to the accompanying drawings. In the following description, the constituent elements having substantially the same function and arrangement are denoted by the same reference numerals, and a repetitive description will be made only when necessary.

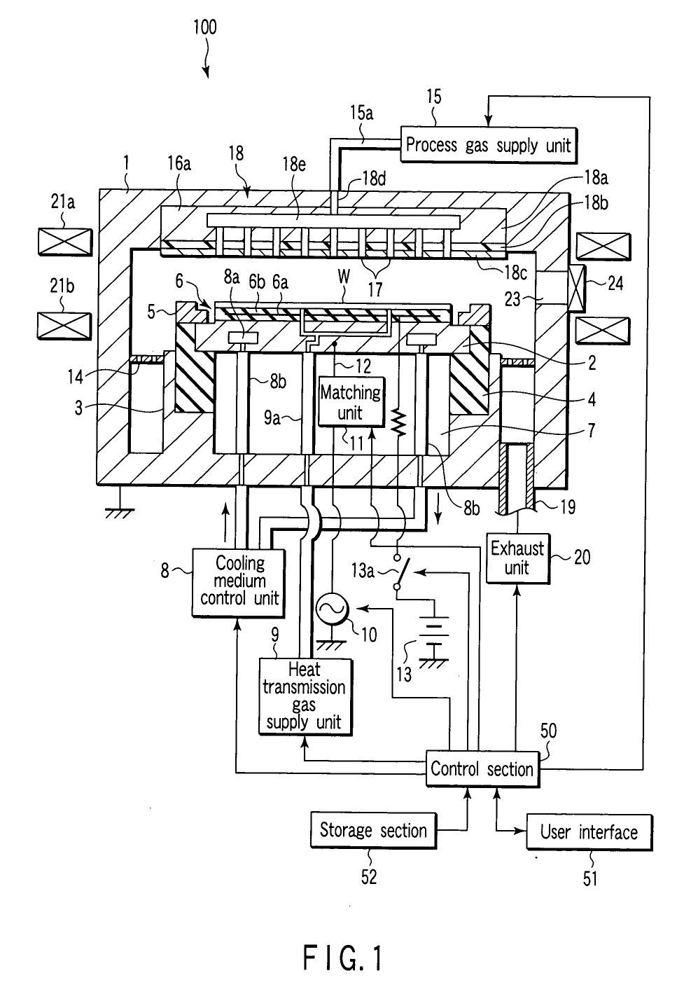

FIG. 1 is a sectional view showing a plasma etching apparatus as a plasma processing apparatus according to an embodiment of the present invention.

This plasma etching apparatus 100 includes an airtight process chamber 1 having an essentially cylindrical shape. For example, the chamber 1 has a main body made of a metal, such as aluminum, with an inner surface covered with an insulating film formed thereon, such as an oxidization processed film, or insulative ceramic film of, e.g. Y₂O₃ (for example, a thermal spraying film). The chamber 1 is grounded.

A support table 2 is disposed in the chamber 1 and configured to horizontally support a target substrate or wafer W and to also serve as a lower electrode. For example, the support table 2 is made of aluminum with an oxidization processed surface. A support portion 3 having a ring shape extends upward from the bottom of the chamber 1 at a position corresponding to the periphery of the support table 2. An insulating member 4 having a ring shape is disposed on the support portion 3, to support the periphery of the support table 2. Further, a focus ring 5 made of a conductive material or insulative material is placed on the periphery of the top of the support table 2. A baffle plate 14 is disposed between the insulating member 4 and the wall of the chamber 1. An inner void 7 is formed between the support table 2 and the bottom of the chamber 1.

The support table 2 is provided with an electrostatic chuck 6 on the top surface, for holding a wafer W by an electrostatic attraction force. The electrostatic chuck 6 comprises an electrode 6a and a pair of insulating layers 6b sandwiching the electrode 6. The electrode 6 is connected to a DC (direct current) power supply 13 through a switch 13a. The semiconductor wafer W is attracted and held by an electrostatic force, e.g. a Coulomb force, generated by a voltage applied from the DC power supply 13 to the electrode 6a.

A cooling medium passage 8a is formed in the support table 2, and is connected to cooling medium lines 8b. A suitable cooling medium is supplied and circulated within the cooling medium passage 8a from a cooling medium control unit 8 through the cooling medium lines 8b to control the support table 2 at a suitable temperature. Further, a heat transmission gas line 9a is disposed to supply a heat transmission gas, such as He gas, into the interstice between the top surface of the electrostatic chuck 6 and the bottom surface of the wafer W. The heat transmission gas is supplied from a heat transmission gas supply unit 9 through the gas line 9a to the bottom surface of the wafer W. Consequently, even when the interior of the chamber 1 is exhausted and maintained in a vacuum state, cold of the cooling medium circulated in the cooling medium passage 8a is efficiently transmitted, thereby improving the temperature control of the wafer W.

A power feed line 12 for supplying an RF (radio frequency) power is connected near the center of the support table 2. The power feed line 12 is connected to a matching unit 11 and an RF power supply 10. The RF power supply 10 is configured to supply an RF power with a predetermined frequency to the support table 2.

On the other hand, a showerhead 18 used as an upper electrode (thus which will be also referred to as an upper electrode 18) is disposed above and opposite the support table 2. The showerhead 18 is fitted in the ceiling of the chamber 1. The showerhead 18 includes a main body 18a made of a metal or semiconductor, such as carbon or Si. The surface of the main body 18a facing the support table 2 is covered with an insulating film 18b for preventing metal contamination, wear-out due to plasma, and generation of scratches. A conductive layer 18c is further stacked on the insulating film 18b. The insulating film 18b is formed of an oxidization processed film, or insulative ceramic film of, e.g. Y₂O₃ (for example, a thermal spraying film).

A number of gas delivery holes 17 are formed to penetrate a lower portion of the main body 18a, the insulating film 18b, and the conductive layer 18c. The gas delivery holes 17 communicate with a space 18e formed in the main body 18a and a gas supply port 18d formed at the top of the main body 18a. The gas supply port 18d is connected through a gas supply line 15a to a process gas supply unit 15 for supplying a process gas for etching.

The upper electrode 18 is grounded through the chamber 1 and cooperates with the lower electrode or support table 2 supplied with an RF power, to define a pair of parallel-plate electrodes. The lower electrode or support table 2 supplied with an RF power serves as a cathode electrode, while the grounded upper electrode 18 serves as an anode electrode. A plasma generation region for turning the process gas into plasma is defined between the upper electrode 18 and support table 2.

As described above, the main body 18a of the upper electrode 18 is covered with the conductive layer 18c, and the surface (conductive counter surface) of the conductive layer 18c facing the support table 2 is exposed to the plasma generation region. As described later in detail, when plasma is generated, an electric current flows through the surface (conductive counter surface) of the conductive layer 18c in the planar direction, and causes the electric field distribution thereon (the potential gradient relative to the ground potential) to be more uniform. Consequently, the plasma potential in the space between the electrodes becomes more uniform, thereby improving the planar uniformity of the plasma process on the wafer W.

The conductive layer 18c preferably covers the entirety of the upper electrode 18, and the area of the conductive layer 18c is preferably set to be equal to or larger than the area of the wafer W placed on the cathode electrode (lower electrode). In other words, the conductive counter surface is preferably disposed to expand over the entirety within a plan view contour equal to or surrounding the plan view contour of the wafer W supported by the support table 2. The method of forming the conductive layer 18c is not limited to a specific one, but may utilize a film formation technique, such as lamination coating, thermal spraying, or CVD.

The process gas for etching can be selected from various conventional process gases, and it may be a gas containing a halogen element, such as a fluorocarbon gas (CₓF_{y}) or hydrofluorocarbon gas (CpHqFᵣ). The process gas may further contain a rare gas, such as Ar or He, N₂ gas, or O₂ gas. Where the process gas is used for ashing, the process gas may be, e.g. O₂ gas.

The process gas is supplied from the process gas supply unit 15 through the gas supply line 15a and gas supply port 18d into the space 18e inside the main body 18a. Then, the process gas is delivered from the gas delivery holes 17 and used for etching a film formed on the wafer W.

The bottom of the chamber 1 is connected through an exhaust line 19 to an exhaust unit 20 including a vacuum pump or the like. The exhaust unit 20 is configured to reduce the pressure inside the chamber 1 to a predetermined vacuum level by the vacuum pump. A transfer port 23 for the wafer W is formed in the upper portion of the sidewall of the chamber 1, and is opened/closed by a gate valve 24 attached thereon.

On the other hand, two ring magnets 21a and 21b are disposed coaxially around the chamber 1 at positions above and below the transfer port 23 of the chamber 1. The ring magnets 21a and 21b are configured to form a magnetic field around the process space between the support table 2 and upper electrode 18. The ring magnets 21a and 21b are rotatable by a rotation mechanism (not shown).

In each of the ring magnets 21a and 21b, a plurality of segment magnets formed of permanent magnets are disposed to be a ring in a multi-pole state. Specifically, in each of the ring magnets 21a and 21b, the magnetic poles of adjacent segment magnets are oriented in opposite directions. Consequently, magnetic force lines are formed between adjacent segment magnets, such that a magnetic field of, e.g. 0.02 to 0.2T (200 to 2000 Gauss), and preferably of 0.03 to 0.045T (300 to 450 Gauss), is formed only around the process space, while essentially no magnetic field is formed at the position where the wafer is placed. Consequently, it is possible to obtain a suitable effect of confining plasma. It should be noted that “essentially no magnetic field is formed at the position where the wafer is placed” is not limited to a case where no magnetic field is present. For example, this concept includes a case where a magnetic field is formed at the position where the wafer is placed, but the magnetic field has essentially no effect on the plasma process.

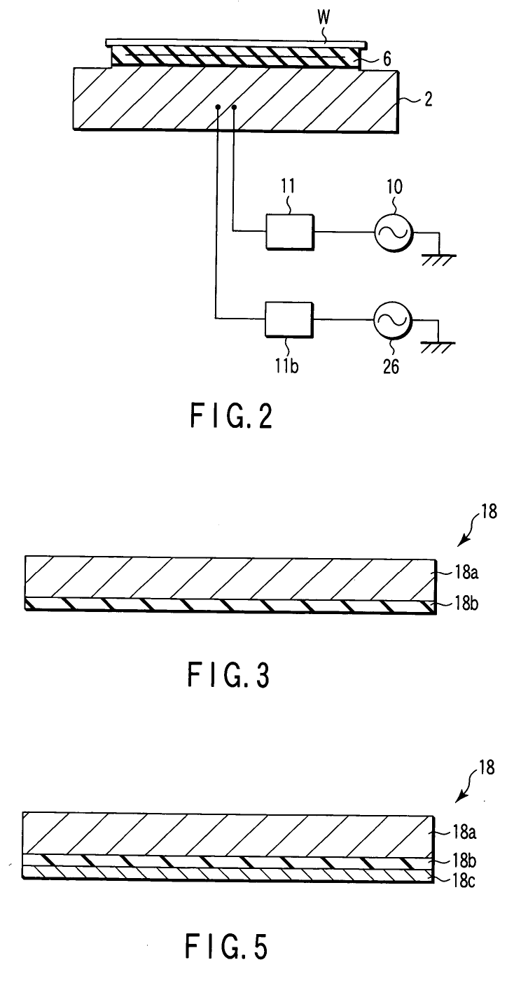

In order to adjust the plasma density and ion attraction, an RF power for plasma generation may be superposed with an RF power for ion attraction from plasma. Specifically, as shown in FIG. 2, in addition to the RF power supply 10 for plasma generation connected to the matching unit 11, an RF power supply 26 for ion attraction is connected to a matching unit 11b to superpose the RF powers. In this case, the RF power supply 26 for ion attraction is preferably set to have a frequency within a range of 500 KHz to 27 MHz. With this arrangement, ion energy can be controlled to further increase the plasma processing rate, such as an etching rate.

The respective components of the plasma etching apparatus 100 are connected to the control section (process controller) 50 and controlled thereby. Specifically, the control section 50 is configured to control the cooling medium control unit 8, the heat transmission gas supply unit 9, the exhaust unit 20, the switch 13a of the DC power supply 13 for the electrostatic chuck 6, the RF power supply 10, and the matching unit 11.

The control section 50 is connected to a user interface 51 including, e.g. a keyboard and a display, wherein the keyboard is used for a process operator to input commands for operating the plasma etching apparatus 100, and the display is used for showing visualized images of the operational status of the plasma processing apparatus 100.

Further, the control section 50 is connected to a storage section 52 that stores control programs for the control section 50 to control the plasma etching apparatus 100 so as to perform various processes, and programs or recipes for respective components of the plasma etching apparatus 100 to perform processes in accordance with process conditions. Recipes may be stored in a hard disk or semiconductor memory, or stored in a portable storage medium, such as a CDROM or DVD, to be attached to a predetermined position in the storage section 52.

A required recipe is retrieved from the storage section 52 and executed by the control section 50 in accordance with an instruction or the like through the user interface 51. As a consequence, the plasma etching apparatus 100 can perform a predetermined process under the control of the control section 50.

Next, an explanation will be given of a process operation of the plasma etching apparatus having the structure described above.

At first, the gate valve 24 of the plasma etching apparatus 100 shown in FIG. 1 is opened, and a wafer W having a layer to be etched is transferred into the chamber 1 and placed on the support table 2 by a transfer arm. After the transfer arm is retreated therefrom and the gate valve 24 is closed, the interior of the chamber 1 is exhausted by the vacuum pump of the exhaust unit 20 through the exhaust line 19 to set the pressure inside the chamber 1 to be a predetermined vacuum level.

Thereafter, a process gas for etching is supplied from the process gas supply unit 15 into the chamber 1 at a predetermined flow rate, so that the pressure inside the chamber 1 is set to be a predetermined value within a range of, e.g. about 0.13 to 133.3 Pa (1 to 1000 mTorr). While the chamber 1 is maintained at a predetermined pressure, an RF power with a frequency of 40 MHz or more, such as 100 MHz, is applied from the RF power supply 10 to the support table 2. At the same time, a predetermined voltage is applied from the DC power supply 13 to the electrode 6a of the electrostatic chuck 6 to attract and hold the wafer W by, e.g. a Coulomb force.

With the RF power applied to the lower electrode or support table 2 as described above, an RF electric field is formed in the process space (plasma generation region) between the upper electrode or showerhead 18 and the lower electrode or support table 2. The process gas supplied into the process space is turned into plasma by the RF electric field, and the etching target layer on the wafer W is etched by the plasma.

During this etching, a magnetic field is formed around the process space by the ring magnets 21a and 21b configured in a multi-pole state. This magnetic field brings about the effect of confining the plasma to make the plasma more uniform, even where the apparatus employs an RF power with a frequency that tends to generate less uniform plasma as in this embodiment. The magnetic field may have no effect, depending on the type of the film, but, in such a case, the segment magnets can be rotated to form essentially no magnetic field around the process space during the process.

When the magnetic field is formed, the conductive or insulative focus ring 5 disposed around the wafer W on the support table 2 enhances the effect of making the plasma process more uniform. Specifically, where the focus ring 5 is made of a conductive material, such as silicon or SiC, the area serving as a lower electrode expands to the focus ring. Consequently, the plasma generation region is enlarged to a position above the focus ring 5, and the plasma generation is promoted on the peripheral portion of the wafer W, thereby improving the etching rate to be more uniform. Where the focus ring 5 is made of an insulative material, such as quartz, the focus ring 5 cannot transfer electric charges to and from electrons and ions in plasma. In this case, the effect of confining plasma is enhanced, thereby improving the etching rate to be more uniform.

As described above, the counter surface of the upper electrode 18 is covered with the conductive layer 18c, and the planar uniformity of the electric field is thereby improved on the surface (conductive counter surface) of the conductive layer 18c, so the plasma process on the wafer W is improved to be more uniform. A detail explanation on this matter will be given below.

FIG. 3 is a view schematically showing the structure of an electrode plate used as an upper electrode in a conventional plasma etching apparatus. Conventionally, as shown in FIG. 3, the surface of the main body 18a of an upper electrode 18 is covered with an insulating film 18b formed thereon, such as an oxidization processed film, or insulative ceramic film of, e.g. Y₂O₃ (for example, a thermal spraying film), for preventing metal contamination and wear-out due to plasma. In this case, the insulating film 18b is the outermost layer, and thus that surface of the upper electrode 18 which is exposed to the plasma generation region is an insulative surface (i.e. the counter surface of the upper electrode 18 is covered with the insulative surface). Further, the inner surface of the chamber 1 is also covered with a similar insulating film.

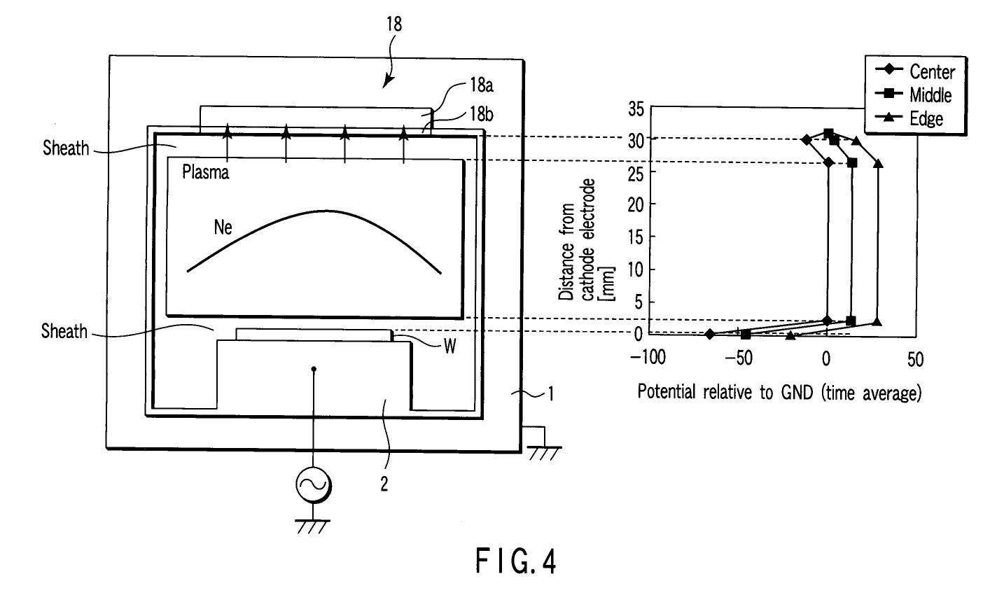

FIG. 4 is a view showing electron density distribution and plasma potential distribution in plasma where the conventional plasma etching apparatus is used. In this apparatus, as shown in FIG. 4, when RF plasma is generated, an RF current flows through the insulating film 18b on the surface of the upper electrode 18 into the main body 18a, but scarcely flows in the radial direction (planar direction) in the surface of the insulating film 18b. With the RF plasma, the insulating film 18b on the surface of the upper electrode 18 comes to have a certain potential distribution in the radial direction, because of, e.g. a poor uniformity of electron density distribution. In this case, the potential distribution remains uneven, and the plasma potential comes to have a poor planar uniformity. Consequently, the support table 2 serving as a cathode electrode or lower electrode receives ion energy incident thereon with a certain planar distribution, thereby deteriorating the planar uniformity of wafer etching.

The conventional technique uses an RF power supply for plasma generation with a frequency of 27 MHz or less and a high process pressure (about 2 to 10 Pa) to generate plasma with a high ion energy. In this case, even if the electrode surface has a certain potential distribution in the radial direction, as described above, no problem is caused. However, some of the recent techniques use an RF power supply with a frequency or 40 MHz or more and a low pressure (1.3 Pa or less) to from plasma with a low electron density (1×10¹⁰/cm³ or less), and also use a negative gas as a process gas. In this case, the plasma has a high resistivity and thus makes the process uniformity poorer. Further, in order to improve the process performance, it is necessary to perform control at low ion energy (100 eV or less). In this case, a poor uniformity of energy due to a poor planar uniformity of the plasma potential cannot be ignored. Specifically, dielectric breakdown (charge-up damage) of a gate oxide film may be caused by a poor planar uniformity of the plasma etching process and a poor uniformity of charge-up on the wafer.

On the other hand, FIG. 5 is a view schematically showing the structure of the electrode plate usable as an upper electrode in the plasma etching apparatus shown in FIG. 1. In order to solve the problems described above, as shown in FIG. 5, this embodiment employs the upper electrode 18 in which the surface of the main body 18a facing the support table 2 is covered with the insulating film 18b, and the conductive layer 18c formed on the surface of the insulating film 18b.

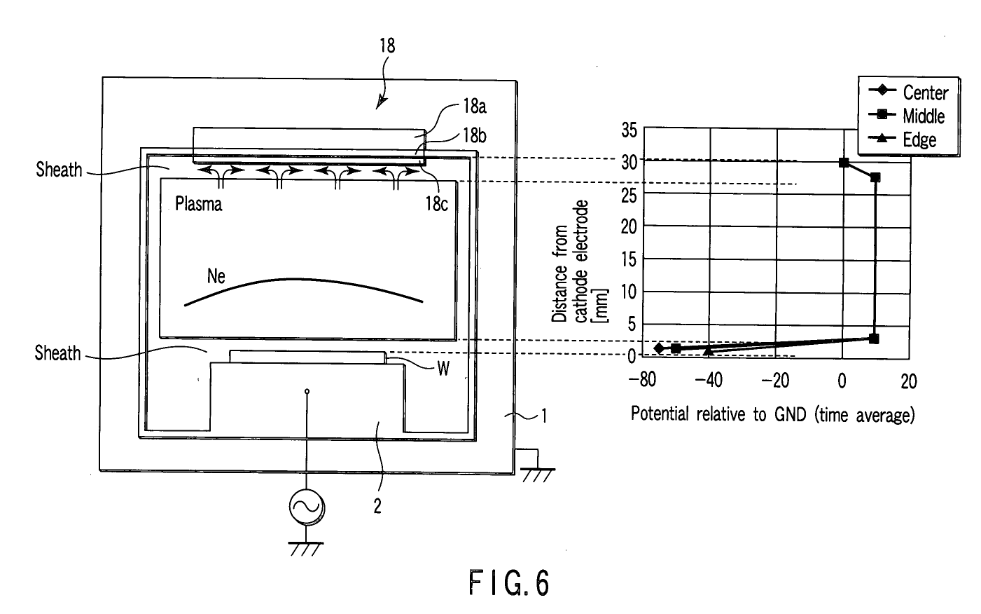

FIG. 6 is a view showing electron density distribution and plasma potential distribution in plasma where the plasma etching apparatus shown in FIG. 1 is used. In this apparatus, when RF plasma is generated, an electric current easily flows on the counter surface of the upper electrode 18 in the radial direction (planar direction). Accordingly, the potential on the counter surface of the upper electrode 18 is made even in the radial direction, so the potential gradient thereon becomes very small in the radial direction. In this case, the plasma potential comes to have essentially no gradient near the upper electrode 18 serving as an anode electrode. Consequently, the support table 2 serving as a cathode electrode or lower electrode receives ion energy incident thereon with a uniform distribution. Further, the uniform ion energy brings about a uniform electron energy in plasma generation, thereby resulting in a uniform electron density distribution. Consequently, it is possible to improve the planar uniformity of the etching process, and reduce the charge-up damage, such as dielectric breakdown of a gate oxide film.

The resistance Rx [Ω] of the conductive layer 18c in a planar X-direction is expressed by the following formula (1).
Rx=(ρ×L₁)/(L₂×X) (1)

In this formula, ρ[Ω·m²/m] denotes the resistivity of the material of the conductive layer 18c, L₁ [m] denotes the reference length of the conductive layer 18c in the X-direction, L₂ [m] denotes the reference length of the conductive layer 18c in a planar Y-direction perpendicular to the X-direction, and t [m] denotes the thickness of the conductive layer 18c.

Since the conductive layer 18c is essentially circular in this embodiment, L₁ L₂ is satisfied. Accordingly, the resistance Rr [Ω] of the conductive layer 18c in the planar radial direction is expressed by ρ/t. In order to exercise the function described above, the resistance Rr [Ω] of the conductive layer 18c in the radial direction is preferably lower. Specifically, Rr [Ω] is preferably set to satisfy Rr [Ω]=ρ/t [Ω]≦1000 [Ω].

On the other hand, the resistance Rz [Ω] of the conductive layer 18c in the thickness direction is expressed by the following formula (2).
Rz=(ρ×t)/(L₁×L₂) (2)

Accordingly, the resistance Rzu [Ω] per unit area of the conductive layer 18c in the thickness direction is expressed by ρ×t. In order to exercise the function described above, the resistance Rzu [Ω] per unit area of the conductive layer 18c in the thickness direction is preferably also lower. Specifically, Rzu[Ω] is preferably set to satisfy Rzu [Ω]=ρ×t [Ω]≦−1 [Ω].

The material of the conductive layer 18c may be Cu, Si, SiC, W, or C (carbon). The material of the conductive layer 18c preferably has a resistivity of 100 Ω·cm or less.

An RF current flows only through a surface portion of a member, and a skin depth δ is defined by the thickness of this surface portion. If the thickness of the conductive layer 18c is smaller than the skin depth δ, an RF current can flow through a portion behind the conductive layer 18c, which brings about a large energy loss. Accordingly, the thickness of the conductive layer 18c is preferably set to be equal to or larger than a skin depth δ expressed by the following formula.

δ=(2/ω σ μ)^{1/2} (where σ is conductivity, μ is magnetic permeability, and ω is the angular frequency of the RF power supply for plasma generation)

According to this embodiment, the conductive layer 18c is formed on the insulating film 18b conventionally used for a protection function, and thus the advantages described are obtained in addition to the conventional protection function. Further, since the conductive layer is formed on a conventional upper electrode, the apparatus structure does not require a large change.

As described above, the area of the conductive layer 18c is preferably set to be equal to or larger than the area of the wafer W. In other words, the conductive counter surface is preferably disposed to expand over the entirety within a plan view contour equal to or surrounding the plan view contour of the wafer W supported by the support table 2. This arrangement enhances the effect of making the potential distribution more uniform.

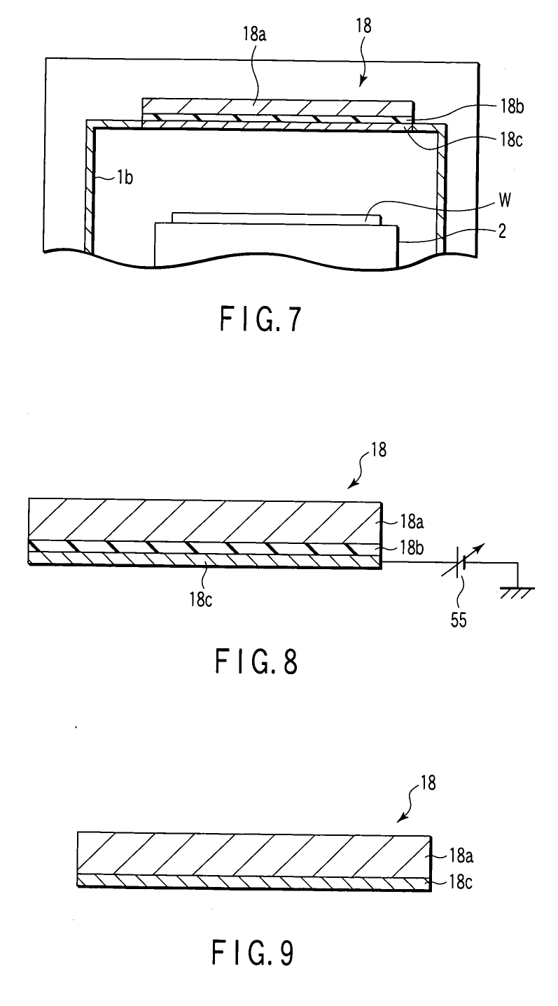

FIG. 7 is a sectional view schematically showing a modification of the apparatus shown in FIG. 1 with a structure where a conductive surface layer is formed on the inner surface of the chamber to be continuous from the conductive layer 18c on the electrode plate. As shown in FIG. 7, where the conductive surface layer 1b is formed on the inner surface of the chamber 1, a current easily flows through the layer 1b, thereby enhancing the effect of making the potential distribution more uniform. In FIG. 7, the conductive surface layer 1b is continuous from the conductive layer 18c on the surface of the upper electrode 18 facing the support table 2, but it may be non-continuous from the conductive layer 18c.

In the apparatus shown in FIG. 1, the conductive layer 18c is disposed on the main body 18a with the insulating film 18b interposed therebetween. In this case, the conductive layer 18c is not coupled with the main body 18a in a sense of DC, and further it is isolated therefrom to be in a floating state in a sense of DC. In contrast, FIG. 8 is a sectional view schematically showing a modification of the apparatus shown in FIG. 1 with a structure where the conductive layer 18c on the electrode plate is grounded through a variable DC power supply 55 connected thereto.

The insulating film 18b is not indispensable to the upper electrode 18. FIG. 9 is a view schematically showing the structure of another electrode plate usable as an upper electrode in the plasma etching apparatus shown in FIG. 1. In this modification, as shown in FIG. 9, a conductive layer 18c is disposed directly on the main body 18a, and coupled therewith in a sense of DC. Consequently, without reference to the material of the main body 18a, a desired conductivity can be realized to effectively exercise the effect described above. In this case, the conductive layer 18c is preferably made of a material high in plasma resistance and scratch resistance.

Alternatively, the upper electrode 18 may be formed of a single conductive body having a desired conductivity. In this case, since the plasma resistance is an important factor, the electrode 18 is preferably formed of a conductive material having high plasma resistance, such as a metal-ceramic complex, e.g. SiC—Al or SIC—S.

Next, an explanation will be given of experiments performed to confirm advantages of the present invention.

At first, a plasma process was performed on a wafer, using an upper electrode according to a conventional structure (comparative example 1), and structures according to the embodiment (present examples 1 and 2). The comparative example 1 was formed of a main body having a counter surface covered with a 250 μm thermal spraying film of Y₂O₃. The present example 1 further had a conductive layer formed of a Cu tape attached to the same structure as the comparative example 1. The present example 2 further had a conductive layer formed of an Si tape attached to the same structure as the comparative example 1.

The wafer was a 300 mm wafer, and the upper electrode had a diameter of 340 mm. A plasma process was performed in the apparatus shown in FIG. 1, under the conditions of: the pressure inside the chamber was set at 0.66 Pa, the process gas was O₂ gas with a flow rate of 200 mL/min, and the RF power was set to be with a frequency of 100 MHz at 500 W and 2400 W. The plasma potential at positions directly above the wafer was measured by probes inserted in the chamber to obtain the planar distribution of the plasma potential Vf relative to the ground potential (GND).

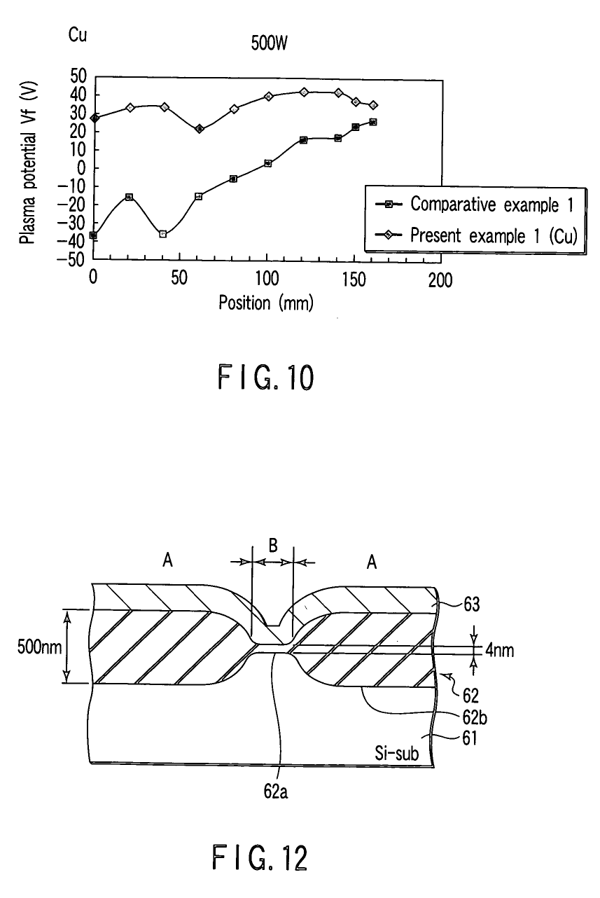

FIG. 10 is a graph showing the plasma potential planar distribution obtained by the present example 1 (an electrode plate with a Cu tape attached thereon as a conductive layer) and the comparative example 1 (a conventional electrode plate), where each of them was used for performing a plasma process on a wafer at an RF power of 500 W. FIGS. 11A and 11B are graphs showing the plasma potential planar distribution obtained by the present example 2 (an electrode plate with a Si tape attached thereon as a conductive layer) and the comparative example 1 (the conventional electrode plate), where each of them was used for performing a plasma process on a wafer at RF powers of 500 W and 2400 W, respectively. As shown in these graphs, it has been confirmed that the conductive layer disposed on the counter surface of the upper electrode remarkably improves the planar uniformity of the plasma potential.

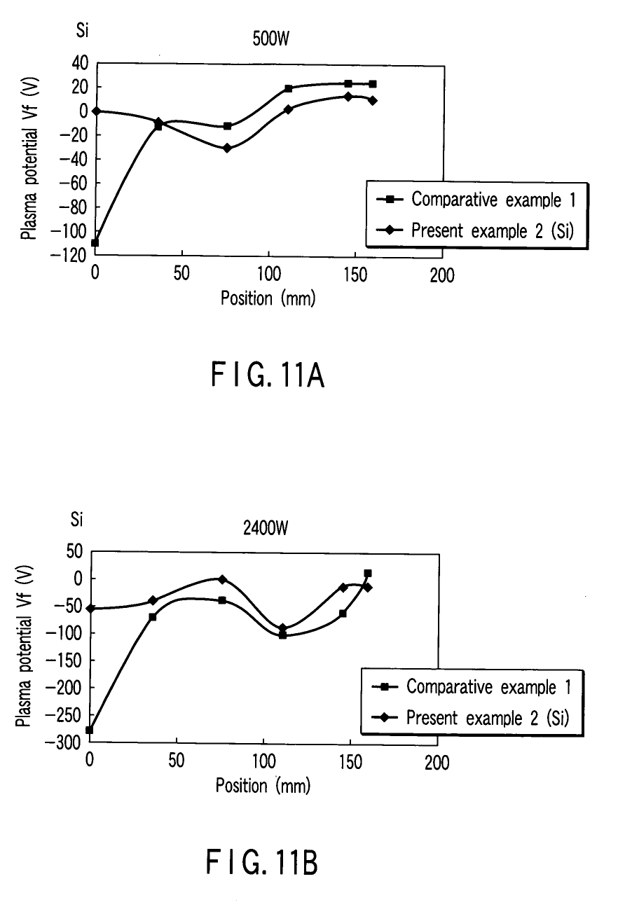

Then, a plasma process was performed on a test wafer, using the comparative example 1 and present example 1, to examine the charge-up damage resistance. FIG. 12 is a view schematically showing a device structure used for testing charge-up damage resistance. As shown in FIG. 12, on an Si substrate 61, an SiO₂ film was formed to have a thickness of 4 nm at a position corresponding to a gate oxide film 62a and a thickness of 500 nm at a position corresponding to a device isolation region 62b, and a poly-silicon film 63 was formed on the SiO₂ film. A number of such devices are formed on the wafer. In order to easily cause charge-up damage, the area A of the device isolation region 62b was set to be 100,000 times the area B of the gate oxide film 62a, wherein this ratio of area A/area B was far larger than ordinary devices.

The wafer was a 300 mm wafer, and the upper electrode had a diameter of 340 mm. A plasma process was performed in the apparatus shown in FIG. 1, under the conditions of: the pressure inside the chamber was set at 0.66 Pa, the process gas was O₂ gas with a flow rate of 200 mL/min, and the RF power was set to be with a frequency of 100 MHz at 500 W. The leakage current of the devices was measured, and, based thereon, it was determined whether dielectric breakdown was caused (where the leakage current was 1×10⁻⁹ A/μm² or more) or not (where the leakage current was smaller than the value).

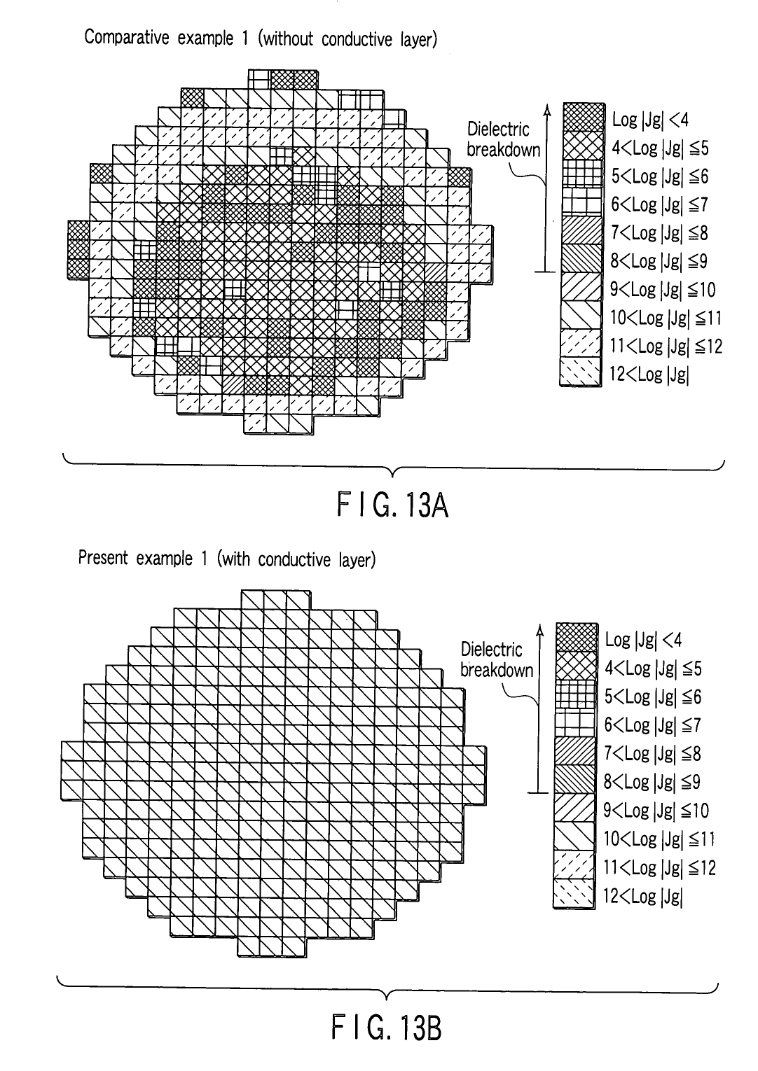

FIGS. 13A and 13B are views showing and comparing generation rates of charge-up damage rendered by the comparative example 1 and present example 1, respectively. As shown in FIGS. 13A and 13B, where the comparative example 1 (an upper electrode with an insulating film surface being exposed) was used, a number of devices rendered dielectric breakdown, while only 43% of the devices did not render dielectric breakdown. On the other hand, where the present example 1 (an upper electrode with a Cu tape surface being exposed) was used, none of the devices rendered dielectric breakdown.

The present invention is not limited to the embodiments described above, and it may be modified in various manners. For example, in the embodiments described above, the ring magnets are used to form a magnetic field around the process space. Each of the ring magnets has a plurality of segment magnets formed of permanent magnets and disposed around the chamber to be a ring in a multi-pole state. However, such magnetic field forming means is not necessarily required. Further, in the embodiments described above, the present invention is applied to plasma etching, but it may be applied to another plasma process, such as plasma CVD or sputtering. Similarly, other apparatus components, the material of the conductive layer, and so forth are not limited to those of the embodiments described above, and they may be modified in various manners. Furthermore, in the embodiments described above, the target substrate is a semiconductor wafer, but it may be applied to another substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A capacitive coupling plasma processing apparatus comprising:
a process chamber configured to have a vacuum atmosphere;
a process gas supply section configured to supply a process gas into the chamber;
a first electrode disposed in the chamber and configured to serve as a cathode electrode;
a second electrode disposed opposite the first electrode in the chamber and grounded to serve as an anode electrode;
an RF power supply configured to supply an RF power to the first electrode to form an RF electric field within a plasma generation region between the first and second electrodes, so as to turn the process gas into plasma by the RF electric field; and
a support member configured to support the target substrate between the first and second electrodes such that a process target surface of the target substrate faces the second electrode,
wherein the second electrode comprises a conductive counter surface facing the first electrode and exposed to the plasma generation region.

2. The apparatus according to claim 1, wherein the conductive counter surface has an area equal to or lager than that of the target substrate.

3. The apparatus according to claim 2, wherein the conductive counter surface is disposed to expand entirely within a plan view contour equal to or surrounding a plan view contour of the target substrate supported by the support member.

4. The apparatus according to claim 1, wherein the second electrode comprises a conductive main body, and a conductive layer disposed on a surface of the main body facing the first electrode, such that the conductive counter surface is defined by a surface of the conductive layer.

5. The apparatus according to claim 4, wherein the conductive layer is not coupled with the main body in a sense of DC.

6. The apparatus according to claim 5, wherein the conductive layer is in a floating state in a sense of DC.

7. The apparatus according to claim 5, further comprising a variable DC power supply connected to the conductive layer, wherein the conductive layer is grounded through the variable DC power supply.

8. The apparatus according to claim 4, wherein the second electrode further comprises an insulating layer interposed between the main body and the conductive layer.

9. The apparatus according to claim 4, wherein the conductive layer has a thickness equal to or larger than a skin depth δ expressed by a formula,
δ=(2/ωσμ)^{1/2}
where σ is conductivity, μ is magnetic permeability, and ω is angular frequency.

10. The apparatus according to claim 4, wherein the conductive layer has a resistance ρ/t in a radial direction, which satisfies a formula,
ρ/t≦1000
where ρ [Ω·m²/m] is resistivity of the conductive layer, and t [m] is thickness of the conductive layer.

11. The apparatus according to claim 4, wherein the conductive layer has a resistance ρ×t per unit area in a thickness direction, which satisfies a formula,
ρ×t≦1
where ρ[Ω·m²/m] is resistivity of the conductive layer, and t [m] is thickness of the conductive layer.

12. The apparatus according to claim 4, wherein the conductive layer consists essentially of a material selected from the group consisting of Cu, Si, SiC, W, and C.

13. The apparatus according to claim 1, further comprising a conductive surface layer disposed on an inner surface of the chamber and exposed to the plasma generation region.

14. The apparatus according to claim 4, wherein the conductive layer is coupled with the conductive main body in a sense of DC.

15. The apparatus according to claim 1, wherein the second electrode is formed of a single conductive body, and the conductive counter surface is defined by a surface of the single conductive body facing the plasma generation region.

16. The apparatus according to claim 15, wherein the second electrode consists essentially of a metal-ceramic complex.

17. The apparatus according to claim 1, wherein the first electrode is combined with the support member.

18. The apparatus according to claim 1, wherein the RF power has a frequency of 40 MHz or more.
